(19) United States
(12) Patent Application Publication
(10) Pub. No.: US 2024/0295761 A1
(43) Pub. Date: Sep. 5, 2024

(54) CIRCULARLY POLARIZATION MODULATION SYSTEM

(71) Applicant: Nippon Telegraph and Telephone Corporation, Tokyo (JP)

(72) Inventors: Hayato Arai, Tokyo (JP); Tomonari Sato, Tokyo (JP); Wataru Kobayashi, Tokyo (JP)

(21) Appl. No.: 18/574,600

(22) PCT Filed: Jul. 6, 2021
(86) PCT No.: PCT/JP2021/025414

§ 371 Date: Dec. 27, 2023

(51) Int. Cl. G02F 1/017; G02F 1/01

(52) U.S. Cl. CPC G02F 1/017; G02F 1/0123; G02F 2203/16

(57) ABSTRACT

A circularly polarized light modulation device includes a stacked structure including at least an n-side electrode, an active layer, and a p-side electrode, an injection current circuit that causes a current to flow from the p-side electrode to the n-side electrode through the active layer, and a spin drive circuit that causes a current to flow in a direction perpendicular to the current injected from the injection current circuit into the stacked structure to at least one of the p-side electrode and the n-side electrode.

### CROSS-REFERENCE TO RELATED APPLICATIONS

This application is a national phase entry of PCT Application No. PCT/JP2021/025414, filed on Jul. 6, 2021, which application is hereby incorporated herein by reference.

### TECHNICAL FIELD

The present invention relates to a light source that emits circularly polarized light, and particularly relates to a circularly polarized light modulation device capable of modulating a rotation direction of the circularly polarized light.

### BACKGROUND

In an optical device, a technology of controlling a state of circularly polarized light by controlling an electron spin in the device has been developed. Since the spin of the carrier used for the emission and recombination corresponds to the emitted circularly polarized light, for example, a technology of emitting circularly polarized light as in the technology disclosed in Non Patent Literature 1 has been achieved. In a device that emits circularly polarized light, in most cases, as in the example of Non Patent Literature 1, a ferromagnetic material such as Fe is magnetized and used as an electrode to inject spin. The magnetization of the ferromagnet has hysteresis characteristics. For this reason, in the structure in which the ferromagnet is magnetized and used as the electrode, there is a problem that the modulation in the rotation direction (clockwise/counterclockwise) of the circularly polarized light cannot be speeded up.

In order to solve this problem, for example, in the technology disclosed in Non Patent Literature 2, modulation is achieved by an optical device including a pair of ferromagnetic electrodes magnetized in opposite directions. However, the technology disclosed in Non Patent Literature 2 can only achieve a modulation rate of about several hundred kHz.

Non Patent Literature 3 discloses a simulation result of a frequency response of modulation of circularly polarized light. According to Non Patent Literature 3, it is shown that a modulation speed as high as 200 to 300 GHz can be achieved by modulation of circularly polarized light. However, in the conventional technology, since a device for controlling spin at a high speed is not achieved, only a modulation speed of about several hundred kHz can be achieved, and high-speed switching of spin to be injected has been a problem.

### CITATION LIST

### Non Patent Literature

Non Patent Literature 1: N. Nishizawa et al., “Pure circular polarization electroluminescence at room temperature with spin-polarized light-emitting diodes”, PNAS, vol. 114, no. 8, pp. 1783-1788, 2017.
Non Patent Literature 2: N. Nishizawa et al., “Arbitrary helicity control of circularly polarized light from lateral-type spin-polarized light-emitting diodes at room temperature”, Applied Physics Express, vol. 11, no. 5, pp. 053003, 2018.
Non Patent Literature 3: M. Lindemann et al., “Ultrafast spin-lasers”, Nature, vol. 568, pp. 212-215, 2019.

### SUMMARY

### Technical Problem

Embodiments of the present invention can solve the above problems, and an object thereof is to provide a circularly polarized light modulation device capable of high-speed modulation of circularly polarized light.

### Solution to Problem

A circularly polarized light modulation device of embodiments of the present invention includes: a stacked structure including at least an n-side electrode, an active layer, and a p-side electrode; an injection current circuit configured to cause a current to flow from the p-side electrode to the n-side electrode through the active layer; and a spin drive circuit configured to cause a current to flow in a direction perpendicular to the current injected from the injection current circuit into the stacked structure, to at least one of the p-side electrode and the n-side electrode.

In addition, in a configuration example of the circularly polarized light modulation device of embodiments of the present invention, the stacked structure further includes a first intermediate layer inserted between the n-side electrode and the active layer, and a second intermediate layer inserted between the active layer and the p-side electrode.

In addition, in a configuration example of the circularly polarized light modulation device of embodiments of the present invention, the first intermediate layer of the stacked structure includes an n-type semiconductor layer, and the second intermediate layer of the stacked structure includes a p-type semiconductor layer.

In addition, in a configuration example of the circularly polarized light modulation device of embodiments of the present invention, the first intermediate layer of the stacked structure further includes a tunnel insulating layer.

In addition, in a configuration example of the circularly polarized light modulation device of embodiments of the present invention, among the p-side electrode and the n-side electrode, an electrode through which the current from the spin drive circuit flows is made of a heavy metal.

In addition, in a configuration example of the circularly polarized light modulation device of embodiments of the present invention, the spin drive circuit can control a direction of a current according to an electric signal input from the outside.

### Advantageous Effects of Embodiments of the Invention

According to embodiments of the present invention, in addition to an injection current circuit of a general device, a spin drive circuit that causes a current to flow in a direction perpendicular to a current injected from the injection current circuit into the stacked structure is provided in at least one of a p-side electrode and an n-side electrode, so that it is possible to switch a rotation direction of circularly polarized light at a high speed using a spin-Hall effect in a metal, and thus it is possible to expand a modulation band.

### BRIEF DESCRIPTION OF THE DRAWINGS

FIG. 1 is a diagram for explaining a spin-Hall effect.

FIG. 2 is a diagram illustrating a configuration of a circularly polarized light modulation device according to a first embodiment of the present invention.

FIG. 3 is a diagram illustrating a configuration of a circularly polarized light modulation device according to a second embodiment of the present invention.

FIG. 4 is a diagram illustrating another configuration of a circularly polarized light modulation device according to a modification of the first embodiment of the present invention.

FIG. 5 is a diagram illustrating another configuration of a circularly polarized light modulation device according to a modification of the second embodiment of the present invention.

FIG. 6 is a diagram illustrating a model of a circularly polarized light modulation device created using an electromagnetic field simulator.

FIGS. 7A and 7B are diagrams illustrating an example of frequency characteristics of a reflection coefficient of a spin drive circuit.

### DETAILED DESCRIPTION OF ILLUSTRATIVE EMBODIMENTS

### First Embodiment

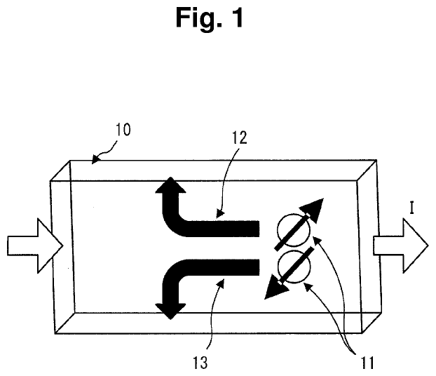

Hereinafter, embodiments of the present invention will be described with reference to the drawings. In embodiments of the present invention, a phenomenon called a spin-Hall effect as illustrated in FIG. 1 is used. The spin-Hall effect is a phenomenon in which a spin current is generated in a direction perpendicular to a current I because a spin dependency occurs in a scattering direction of electrons 11 when the current I is caused to flow in a heavy metal 10 such as Pt, Ta, or W. In FIG. 1, reference numeral 12 denotes a flow of upward spin electrons, and reference numeral 13 denotes a flow of downward spin electrons. The spin-Hall effect is a phenomenon that occurs in most solids (metal, semiconductor), but the effect is remarkably exhibited by heavy metals, particularly Pt, Ta, W, Au—Pt alloys, and the like, and thus it is desirable to use these materials as electrodes of a device.

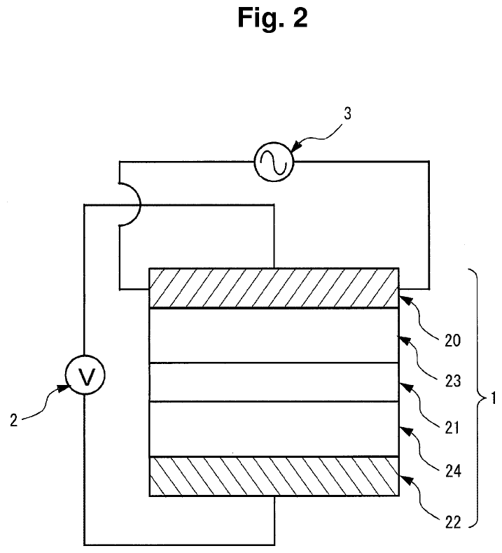

FIG. 2 is a diagram illustrating a configuration of a circularly polarized light modulation device according to a first embodiment of the present invention. A circularly polarized light modulation device includes: a stacked structure 1 including at least an n-side electrode 20, an active layer 21, and a p-side electrode 22; an injection current circuit 2 that causes a current to flow from the p-side electrode 22 to the n-side electrode 20 through the active layer 21; and a spin drive circuit 3 that causes a current to flow in a direction perpendicular to the current injected from the injection current circuit 2 into the stacked structure 1, to at least one of the p-side electrode 22 and the n-side electrode 20.

The stacked structure 1 includes the n-side electrode 20, the active layer 21, the p-side electrode 22, an intermediate layer 23 inserted between the n-side electrode 20 and the active layer 21, and an intermediate layer 24 inserted between the active layer 21 and the p-side electrode 22.

The intermediate layers 23, 24 may be conductors, for example, may include n-doped semiconductors, or may include thin insulating layers.

The present embodiment illustrates an example in which the spin drive circuit 3 causes a current to flow only through the n-side electrode 20. Therefore, it is desirable to use a heavy metal such as Pt, Ta, W, or an Au—Pt alloy as the material of the n-side electrode 20, but a material other than the heavy metal may be used for the p-side electrode 22.

In the present embodiment, a spin current is generated in a direction parallel to an injection current injected from the injection current circuit 2 into the stacked structure 1 by a current (referred to as a spin drive current) flowing from the spin drive circuit 3 to the n-side electrode 20, and the spin current is injected into the active layer 21 together with the injection current, so that circularly polarized light is emitted from the active layer 21.

The spin drive circuit 3 can control the direction of the current according to an electric signal input from the outside. When the direction of the spin drive current is reversed, the direction of the spin current is also reversed, and the circularly polarized light is also reversed, so that the circularly polarized light can be modulated by the spin drive current.

As described above, in the present embodiment, the direction of the spin current can be controlled by using the spin-Hall effect in the metal without using the ferromagnetic material such as Fe when injecting the spin-polarized electrons into the active layer 21, and high-speed modulation of the circularly polarized light by the electric signal can be achieved.

### Second Embodiment

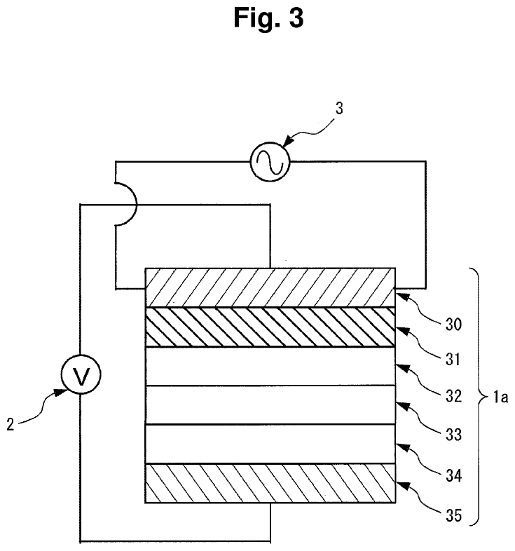

Next, a second embodiment of the present invention will be described. FIG. 3 is a diagram illustrating a configuration of a circularly polarized light modulation device according to the second embodiment of the present invention. The present embodiment applies to a stacked structure 1a constituting a pin-bonded LED.

The stacked structure 1a includes a p-side electrode 35, a p-type semiconductor layer 34 formed on the p-side electrode 35, an active layer 33 formed on the p-type semiconductor layer 34, an n-type semiconductor layer 32 formed on the active layer 33, a tunnel insulating layer 31 formed on the n-type semiconductor layer 32, and an n-side electrode 30 made of Pt formed on the tunnel insulating layer 31. The n-type semiconductor layer 32 and the tunnel insulating layer 31 correspond to the intermediate layer 23 in FIG. 2, and the p-type semiconductor layer 34 corresponds to the intermediate layer 24.

In the present embodiment, Pt is used as the material of the n-side electrode 30 because the spin drive circuit 3 causes a spin drive current to flow through the n-side electrode 30, but a material other than heavy metals may be used for the p-side electrode 35.

The tunnel insulating layer 31 is for reducing spin relaxation at the time of spin injection from the n-side electrode 30 into the active layer 33.

Similar to the first embodiment, a spin current is generated in a direction parallel to an injection current injected from the injection current circuit 2 into the stacked structure 1a by a spin drive current flowing from the spin drive circuit 3 to the n-side electrode 30, and the spin current is injected into the active layer 33 together with the injection current, so that circularly polarized light is emitted from the active layer 33. When the direction of the spin drive current is reversed, the direction of the spin current is also reversed, and the circularly polarized light is also reversed, so that the circularly polarized light can be modulated by the spin drive current.

In the present embodiment, the case where the stacked structure 1a is an LED has been described, but embodiments of the present invention can also be applied to a device that emits and amplifies light by emission and recombination of carriers, such as a laser and a semiconductor optical amplifier.

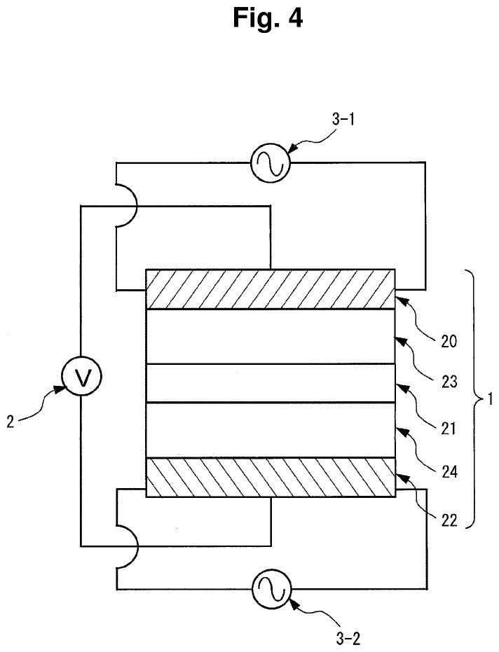

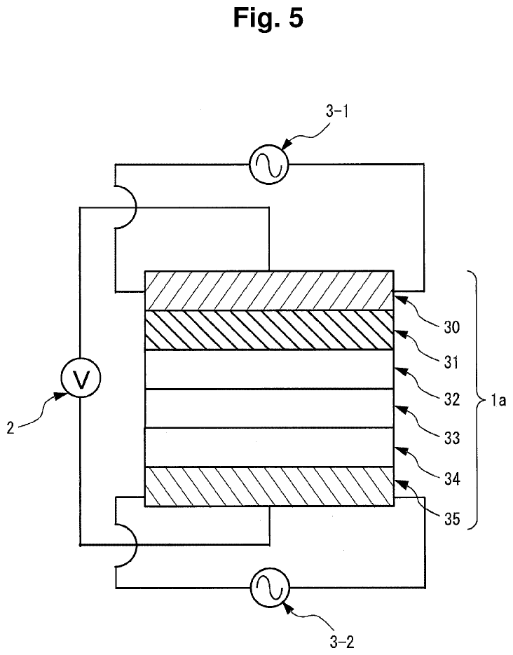

As described above, it is also possible to cause the spin drive current to flow through the p-side electrode by the spin drive circuit. FIG. 4 illustrates a configuration in which a spin drive current flows through both the n-side electrode 20 and the p-side electrode 22 in the first embodiment, and FIG. 5 illustrates a configuration in which a spin drive current flows through both the n-side electrode 30 and the p-side electrode 35 in the second embodiment.

Since the direction of the spin current is determined by the difference between the flow of upward spin electrons and the flow of downward spin electrons, the direction of the spin current can be controlled by adjusting the balance between the spin drive current flowing from the spin drive circuit 3-1 to the n-side electrodes 20, 30 and the spin drive current flowing from the spin drive circuit 3-2 to the p-side electrodes 22, 35.

It is needless to say that, when the spin drive current flows only to the p-side electrodes 22, 35, only the spin drive circuit 3-2 is required to be provided.

### Third Embodiment

Next, a third embodiment of the present invention will be described. In the present embodiment, the effect of an embodiment of the present invention is verified using a circuit simulator. In the device illustrated in FIG. 3, two factors of (1) the frequency of the spin drive circuit and (2) the time constant of the spin-Hall effect are considered as the rate limiting factor of the modulation rate.

First, the influence of the frequency characteristics of the spin drive circuit on the modulation speed of the circularly polarized light modulation device will be verified. When the response of the spin drive current is slow with respect to the voltage applied to the spin drive circuit, the spin drive circuit becomes a rate limiting factor of the modulation rate.

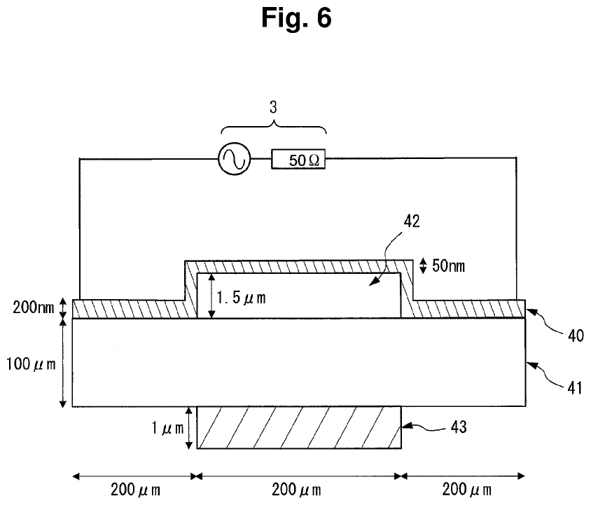

Here, a model of a circularly polarized light modulation device as illustrated in FIG. 6 was created using ver. 16.56 of the electromagnetic field simulator SONNET (registered trademark), and the frequency characteristics of the spin drive circuit were calculated. In the example of FIG. 6, a model of a stacked structure including a GaAs substrate 41, an AlGaAs/GaAs-LED 42 grown on the GaAs substrate 41, a Pt channel 40 serving as an n-side electrode, and a p-side electrode 43 on the back surface of the substrate is created. The GaAs substrate 41 and the AlGaAs/GaAs-LED 42 correspond to the active layer 21 and the intermediate layers 23, 24 in FIG. 2.

The thickness of the Pt channel 40 is 50 nm, the thickness of the GaAs substrate 41 is 100 μm, the thickness of the AlGaAs/GaAs-LED 42 is 1.5 μm, and the thickness of the p-side electrode 43 is 1 μm. The dielectric constant of the GaAs substrate 41 and the AlGaAs/GaAs-LED 42 was set to 9.0, the resistivity of the Pt channel 40 was set to 1.05×10⁻⁷ Ωm, and the resistivity of the p-side electrode 43 was set to 1×10⁻⁷ Ωm. An AC power supply having an output impedance of 50Ω was used as the spin drive circuit 3.

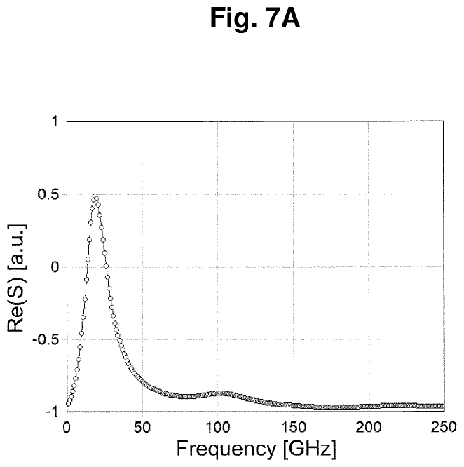

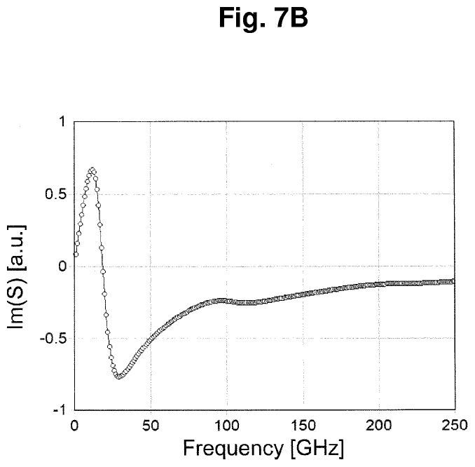

FIGS. 7A and 7B illustrate the frequency characteristics of the reflection coefficient of the spin drive circuit 3 calculated under the above conditions. FIG. 7A illustrates the frequency characteristics of the real part Re (S) of the reflection coefficient, and FIG. 7B illustrates the frequency characteristics of the imaginary part Im (S) of the reflection coefficient.

According to FIGS. 7A and 7B, a resonance peak was confirmed in the vicinity of 19 GHz, but S=−1 is established at other frequencies, which indicates that the frequency is close to a short circuit. In embodiments of the present invention, it is important whether the spin drive current output from the spin drive circuit 3 follows the AC power supply voltage input to the spin drive circuit 3. Therefore, according to the results of FIGS. 7A and 7B, it has been found that the AC power supply can operate as the spin drive circuit 3 up to around 250 GHz except for the vicinity of the resonance point.

Next, the influence of the time constant of the response due to the spin-Hall effect on the modulation speed of the circularly polarized light modulation device will be verified. In order to investigate the dynamic behavior of the spin-Hall effect, it has been proposed to treat electrons as particles according to a one-dimensional diffusion equation and to solve an equation to which a term representing the spin-Hall effect is added (Document ‘N. P. Stern et al., “Time-resolved dynamics of the spin Hall effect”, Nature Physics, vol. 4, pp. 843-846, 2008’).

Using a similar model, the time constant TSH of the response by the spin-Hall effect can be expressed as the following expression.

$${τ}_{SH} = \frac{{τ}_{S}}{1 + {{π}^{2} ( \frac{{L}_{S}}{d} )}^{2}} \qquad ( 1 )$$

In Expression (1), τₛ is the spin relaxation time, Lₛ is the spin diffusion length, and d is the thickness of the Pt channel 40. When the thickness d of the Pt channel 40 is set to 50 nm, which is the same as the model illustrated in FIG. 6, and the values at room temperature disclosed in the document ‘R. Freeman et al., “Evidence for Dyakonov-Perel-like Spin Relaxation in Pt”, Physical Review Letters, vol. 120, pp. 067204, 2018’ are used with the spin relaxation time τs and the spin diffusion length Lₛ, the time constant τ_{SH}=194 fs is obtained. The value of the spin relaxation time τₛ used for the calculation is 0.2 ps, and the value of the spin diffusion length Lₛ is 3.7 nm. When the time constant τ_{SH}=194 fs is converted into the 3 dB cutoff frequency, f_{3dB}=819 GHz is established, which is a value equal to or more than the operable frequency of the spin drive circuit 3.

From the estimation result of the frequency characteristics of the spin drive circuit 3 and the estimation result of the time constant of the spin-Hall effect, it can be said that a modulation speed of about 250 GHz can be expected.

### INDUSTRIAL APPLICABILITY

Embodiments of the present invention can be applied to a light source that emits circularly polarized light.

### REFERENCE SIGNS LIST

1, 1a Stacked structure
2 Injection current circuit
3, 3-1, 3-2 Spin drive circuit
20, 30 n-side electrode
21, 33 Active layer
22, 35, 43 p-side electrode
23, 24 Intermediate layer
31 Tunnel insulating layer
32 n-type semiconductor layer
34 p-type semiconductor layer
40 Pt Channel
41 GaAs substrate
42 AlGaAs/GaAs-LED

1.-6. (canceled)

7. A circularly polarized light modulation device, the device comprising:
a stacked structure comprising an n-side electrode, an active layer, and a p-side electrode;
an injection current circuit configured to cause a first current to flow from the p-side electrode to the n-side electrode through the active layer; and
a spin drive circuit configured to cause a second current to flow to the p-side electrode or the n-side electrode in a direction perpendicular to the first current injected from the injection current circuit into the stacked structure.

8. The device according to claim 7, wherein the stacked structure further comprises:
a first intermediate layer inserted between the n-side electrode and the active layer; and
a second intermediate layer inserted between the active layer and the p-side electrode.

9. The device according to claim 8, wherein:
the first intermediate layer of the stacked structure comprises an n-type semiconductor layer; and
the second intermediate layer of the stacked structure comprises a p-type semiconductor layer.

10. The device according to claim 9, wherein the first intermediate layer of the stacked structure further comprises a tunnel insulating layer.

11. The device according to claim 10, wherein the spin drive circuit is configured to cause the second current to flow to the p-side electrode in the direction perpendicular to the first current injected from the injection current circuit into the stacked structure, and wherein the p-side electrode comprises a heavy metal.

12. The device according to claim 10, wherein the spin drive circuit is configured to cause the second current to flow to the n-side electrode in the direction perpendicular to the first current injected from the injection current circuit into the stacked structure, and wherein the n-side electrode comprises a heavy metal.

13. The device according to claim 10, wherein the spin drive circuit is configured to control the direction of the second current according to an electric signal input from an outside.

14. The device according to claim 7, wherein the spin drive circuit is configured to cause the second current to flow to the p-side electrode in the direction perpendicular to the first current injected from the injection current circuit into the stacked structure, and wherein the p-side electrode comprises a heavy metal.

15. The device according to claim 7, wherein the spin drive circuit is configured to cause the second current to flow to the n-side electrode in the direction perpendicular to the first current injected from the injection current circuit into the stacked structure, and wherein the n-side electrode comprises a heavy metal.

16. The device according to claim 7, wherein the spin drive circuit is configured to control the direction of the second current according to an electric signal input from an outside.

17. A circularly polarized light modulation device, the device comprising:
a stacked structure comprising an n-side electrode, an active layer, and a p-side electrode;
an injection current circuit configured to cause a first current to flow from the p-side electrode to the n-side electrode through the active layer;
a first spin drive circuit configured to cause a second current to flow to the n-side electrode in a direction perpendicular to the first current injected from the injection current circuit into the stacked structure; and
a second spin drive circuit configured to cause a third current to flow to the p-side electrode in the direction perpendicular to the first current injected from the injection current circuit into the stacked structure.

18. The device according to claim 17, wherein the stacked structure further comprises:
a first intermediate layer inserted between the n-side electrode and the active layer; and
a second intermediate layer inserted between the active layer and the p-side electrode.

19. The device according to claim 18, wherein:
the first intermediate layer of the stacked structure comprises an n-type semiconductor layer; and
the second intermediate layer of the stacked structure comprises a p-type semiconductor layer.

20. The device according to claim 19, wherein the first intermediate layer of the stacked structure further comprises a tunnel insulating layer.

21. The device according to claim 20, wherein the n-side electrode comprises a first heavy metal and the p-side electrode comprises a second heavy metal.

22. The device according to claim 20, wherein the first spin drive circuit is configured to control the direction of the second current according to an electric signal input from an outside.

23. The device according to claim 17, wherein the n-side electrode comprises a first heavy metal and the p-side electrode comprises a second heavy metal.

24. The device according to claim 17, wherein the first spin drive circuit is configured to control the direction of the second current according to an electric signal input from an outside.
